(19) United States
(12) Patent Application Publication
(10) Pub. No.: US 2001/0010374 A1
(43) Pub. Date: Aug. 2, 2001

(54) Thin-film display system

(75) Inventor: Ichiro Takayama, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: TDK CORPORATION, Tokyo (JP)

(21) Appl. No.: 09/740,866

(22) Filed: Dec. 21, 2000

(30) Foreign Application Priority Data
Jan. 27, 2000 (JP) 2000-018659

(51) Int. Cl. H01L 33/00

(52) U.S. Cl. 257/98; 438/1

(57) ABSTRACT

The invention provides a thin-film display system comprising, on the same substrate 1, a thin-film display device 9 driven at a current for each pixel to emit light and a silicon thin-film layer 2 on which a circuit for driving the thin-film display device 9 is formed. The display system further comprises a region where at least the thin-film display device 9 and the silicon thin-film layer overlap each other in a film thickness direction, so that a part of light emitted from the thin-film display device is taken out of that region.

### BACKGROUND OF THE INVENTION

1. Field of the Invention

The present invention relates generally to a thin-film display system using thin-film light emitting devices such as organic electroluminescence (EL) devices.

2. Background Art

In recent years, thin-film display systems using organic EL devices or the like have been developed. For instance, when a thin-film display system comprising a multiplicity of organic EL devices is set up using an active matrix circuit, pixels of each EL are each connected with a set of FETs (field effect transistors) like thin-film transistors (TFTs) for controlling a current fed to each pixel. In other words, each pixel is connected with a set of a biasing TFT for feeding a driving current to an organic EL device and a switching TFT indicative of whether or not that biasing TFT is to be selected.

FIGS. 10 and 11 show one exemplary construction of a conventional active matrix type of organic EL display system. This organic EL display system 50 are built up of a screen 51, and elements for driving the screen 51, for instance, X-direction signal lines X1, X2, , Y-direction signal lines Y1, Y2, . . . power source Vdd lines Vdd1, Vdd2, . . . , switching TFT transistors Ty11, 12, Ty21, 22, . . . , current controlling TFT transistors M11, M12, M21, M22, . . . ,organic EL devices EL110, 120, EL210, 220, . . . , capacitors C11, 12, C21, 22, , an X-direction peripheral driving circuit (shift register X-axis) 52, and a Y-direction peripheral driving circuit (shift register Y-axis) 53.

A pixel is specified by X-direction signal lines X1, X2 and Y-direction signal lines Y1, Y2. At that pixel, switching TFT transistors Ty11, 12, Ty 21, 22 are put on, so that image data are held on signal holding capacitors C11, 12, C21, 22. This in turn puts on current controlling TFT transistors M11, 12, M21, 22, so that biasing currents corresponding to the image data are passed through organic EL devices EL110, 120, EL210, 220 via power source lines Vdd1, Vdd2 for light emission.

For instance, as signals corresponding to the image data are produced at X-direction signal line X1 and Y-direction scanning signals are produced at Y-direction signal line Y1, switching TFT transistor Ty11 for the pixel specified thereby is put on, so that current controlling TFT transistor M11 is brought into conduction by signals corresponding to the image data, whereupon a light emission current corresponding to the image data is passed through organic EL device EL110 for light emission control. In an active matrix type of EL image display system comprising, per pixel, a thin-film type EL device, a current controlling TFT transistor for controlling the light emission of the EL device, a signal holding capacitor connected to a gate electrode of the current controlling TFT transistor, a switching TFT transistor for writing data into the capacitor, etc., the light emission intensity of the EL device is thus determined by a current passing through the TFT transistor that is a light emission current controlling non-linear device controlled by a voltage built up in the signal holding capacitor (see A66-in 201 pi Electroluminescent Display T. P. Brody, F. C. Luo, et. al, IEEE Trans Electron Devices, Vol. ED-22, No. 9, Sep. 1975, P739-P749).

The capacity of the signal holding capacitor used must be equal to or less than the capacity at which the pixel switching TFT transistor allows sufficient charges to be charged therein within a very short selection time. This capacity must also be such that a capacitor's holding voltage drop has no adverse influence on the image quality of a display panel, because the charges are lost by the next writing time due to current leakage occurring during a non-selection time of the pixel switching TFT transistor.

On the other hand, JP-A 5-258861 discloses using an inorganic EL for a light emitting device and a method of forming a TFT of a-Si and capacity on the EL device depending on material and fabrication processes. However, the use of such an inorganic EL device makes it difficult to achieve low voltage and high luminance.

When such an organic EL device as mentioned above is used for a light emitting layer, on the other hand, it is required to use a material having a work function of 4 eV or less, for instance, an alloy such as MgAg or a metal material for an electron feeding cathode, and use a transparent conductive thin film for an anode on the substrate side out of which the emitted light is taken. In other words, low voltages and high luminance may be achieved by use of the organic EL device. In view of the material and fabrication process of the organic EL device, however, it is impossible to make use of such a structure as set forth in the aforesaid JP-A 5-258861.

A conventional thin-film display system using organic EL devices is now explained more specifically with reference to FIGS. 12 and 13. FIG. 12 is a plan view illustrative of one embodiment of a TFT array for driving the organic EL devices, and FIG. 13 is a sectional view taken along section A-A′ in FIG. 12.

As shown in FIG. 12, a source bus 11 is connected with a source electrode 13, and then connected to a source site formed on a silicon substrate 21 via a contact hole 13a. The silicon substrate 21 is provided thereon with a gate bus 12 commonly connected to a TFT element of another pixel (not shown). A gate electrode is formed at a site where the gate bus 12 intersects the silicon substrate 21.

A drain site formed on the silicon substrate with a source site and a gate electrode interposed between them is connected with a drain wire 14 via a contact hole 14a. The drain wire 14 is connected to a gate line 15. The gate line 15 is formed on a silicon substrate 22 forming a TFT 2, and connected to one electrode of a capacitor 18. The other electrode of the capacitor 18 is connected to an earth bus 23 and a source electrode 17. The source electrode 17 is connected to a source site of a TFT1 via a contact hole 17a. A gate electrode is formed at a site where the gate line 15 intersects the silicon substrate 22.

A drain site formed on a silicon substrate with a source site and gate electrode 15 interposed between them is connected with a drain wire 16 via a contact hole 16a. The drain wire 16 forms one electrode 7 of the organic EL device defining a pixel or, alternatively, is connected thereto.

Referring to FIG. 13, an active p-Si layer is formed on a substrate 1, and provided thereon with an insulating gate 3 and a gate electrode 4. A drain electrode 17 and a source electrode 16 are provided with the gate electrode interposed between them, and the source electrode 16 is connected with an ITO 7 that defines an electrode of an organic EL structure 9. An edge cover 8, out of which emitted light is taken, has an opening 8a over a region on which TFT elements, etc. are not formed. The reasons why the opening is provided over such a region alone are that a region through which the emitted light does not pass is covered with the edge cover for the purposes of improving energy efficiency, reducing an increase in the capacity between the ITO and the electrode formed thereon, etc.

In the display system of such construction, increases in the number and size of driving switching elements such as TFTs and other circuit parts in each pixel are found to result in a decrease of the proportion in the pixel of the organic EL device contributing to light emission. To make up for this decrease, there is no other choice but to increase the light emission luminance of the organic EL device. However, this is not desired because extraordinary loads are imposed on the organic EL device and so cause damage to its reliability.

### SUMMARY OF THE INVENTION

An object of the present invention is to increase the proportion of a thin-film light emitting device in a pixel, thereby providing a high-luminance yet high-reliability thin-film display system of the active matrix type.

The aforesaid object is achievable by the following embodiments of the present invention.

(1) A thin-film display system comprising, on the same substrate, a thin-film display device driven at a current for each pixel to emit light and a silicon thin-film layer on which a circuit for driving the thin-film display device is formed, which further comprises a region where at least said thin-film display device and said silicon thin-film layer overlap each other in a film thickness direction, wherein a part of light emitted from said thin-film display device is taken out of said region.

(2) The thin-film display system according to (1) above, wherein said silicon thin-film layer is provided with a switching element for driving said thin-film light emitting device.

(3) The thin-film display system according to (1) or (2) above, wherein a part of light emitted from said thin-film display device is taken out of a region with said switching element formed thereon.

(4) The thin-film display system according to any one of (1) to (3) above, wherein at least a part of a channel region in said switching element is shielded from light by a material having no light transmission properties.

(5) The thin-film display system according to any one of (1) to (4) above, wherein a control electrode for said switching element is formed of a material opaque to light.

(6) The thin-film display system according to any one of (1) to (5) above, wherein said switching element is formed of a polysilicon thin film.

(7) The thin-film display system according to any one of (1) to (6) above, wherein said switching element is a thin-film transistor.

(8) The thin-film display system according to any one of (1) to (7) above, wherein said thin-film display device is an organic EL device.

### BRIEF DESCRIPTION OF THE DRAWINGS

FIG. 1 is a partly sectioned view illustrative of one embodiment of the thin-film display system according to the present invention, corresponding to a view taken along section A-A′ of FIG. 2.

FIG. 2 is a partial plan view of one embodiment of the thin-film display system according to the present invention.

FIG. 3 is a partly sectioned view of another embodiment of the thin-film display system according to the present invention.

FIG. 4 is a partly sectioned sketch illustrative of the fabrication process of the organic EL device driver according to the present invention.

FIG. 5 is a partly sectioned sketch illustrative of the fabrication process of the organic EL device driver according to the present invention.

FIG. 6 is a partly sectioned sketch illustrative of the fabrication process of the organic EL device driver according to the present invention.

FIG. 7 is a partly sectioned sketch illustrative of the fabrication process of the organic EL device driver according to the present invention.

FIG. 8 is a partly sectioned sketch illustrative of the fabrication process of the organic EL device driver according to the present invention.

FIG. 9 is a partly sectioned sketch illustrative of the fabrication process of the organic EL device driver according to the present invention.

FIG. 10 is a schematic illustrative of one example of the circuit diagram for a conventional active matrix type of organic EL display system.

FIG. 11 is an enlarged view for a region indicated by A in FIG. 13.

FIG. 12 is a partial plan view illustrative of one exemplary construction of a conventional organic EL display system.

FIG. 13 is a sectional view taken along section A-A′ of FIG. 11.

### BEST MODE OF CARRYING OUT THE INVENTION

The thin-film display system of the present invention comprises, on the same substrate, a thin-film display device driven at a current for each pixel to emit light and a silicon thin-film layer on which a circuit for driving the thin-film display device is formed. The display system further comprises a region where at least the thin-film display device and the silicon thin-film layer overlap each other in a film thickness direction, and a part of light emitted from the thin-film display device is taken out of that region.

Preferably, the aforesaid silicon thin-film layer is provided with a switching element, so that a part of light emitted from the aforesaid thin-film display device is taken out of a region with the aforesaid switching element formed thereon. At least a part of a channel region in the aforesaid switching element is preferably shielded from light by a material having no light transmission properties.

By forming at least some regions of the silicon thin-film layer, especially its switching element and the thin-film display device in such a way as to overlap each other, it is further possible to take the emitted light out of the region with the switching element formed thereon. It is also possible to increase the proportion of the light emitting region in the pixel, thereby enhancing the light emission luminance of the pixel. Furthermore, an increase in the area of the light emitting region makes it possible to relatively enhance the luminance of the pixel without enhancing the light emission of the thin-film light emitting device per se, thereby making some contributions to improvements in the reliability of the device.

Usually, the polysilicon (p-Si) layer with a switching element such as a thin-film transistor (TFT) formed thereon is transparent to a visible range of light, too. For this reason, it is possible to take the emitted light out of the region with the switching element formed. By forming at least some regions of the silicon thin-film layer (switching element) and thin-film display device in such a way as to overlap each other, in other words, by forming at least some regions of the silicon thin-film layer (switching element) and thin-film display device in such a way as to overlap each other in the film thickness direction, it is also possible to take the emitted light out of the silicon thin-film layer, especially the region with the switching element formed thereon, thereby extending the substantial light emitting area without enhancing the light emission luminance of the device per se.

Furthermore, the emitted light can be taken out of not only the switching element itself but also an island form of free area available for alignment and wire running, etc., and so the light emitting area can be sufficiently extended even when the emitted light is taken out of a region other than the region with the switching element (TFT) formed thereon.

According to the present invention, the light emitted from the thin-film display device can be taken out of a region other than the region on which the anode (or cathode) of the thin-film display device is formed and which defines an ordinary light extraction region, as explained above. Such construction enables the light emitting region to be so extended that the light emission luminance of the pixel can be substantially increased without enhancing the light emission luminance of the device itself.

In some cases, the off performance, threshold value and other characteristics of the switching element (TFT) vary if not largely, upon incidence of emitted light on the thin-film light emitting device, especially the region with the switching element (TFT) formed thereon as well as at least a part of the channel region or the region with the control electrode (gate) formed thereon. This is because carriers are generated by few photons absorbed in the silicon thin-film layer (p-Si layer). Such changes of characteristics become an obstacle to high-quality displays. To avoid this, the region with the switching element formed thereon, especially at least a part of the channel region or the region with the control electrode (gate) formed thereon may be covered with a light shielding film opaque to light. In this case, the emitted light cannot be taken out of the region with the switching element formed thereon, especially the region with the control electrode formed thereon. Still, it is possible to achieve full extension of the light emitting region with respect to the whole pixel.

For the light shielding film, it is acceptable to use any desired material that has a light transmission property of 70% or less, and especially 90% or less, with respect to emitted light. However, it is particularly preferable to make use of the material forming the thin-film display system because fabrication processes can be simplified with some cost reductions. The material that forms this thin-film display device, for instance, includes metals such Al, Cu, Cr, Ti, Mo, V, Zr, W and Ta, metal alloys such as Ni-Cr, nitrides such as titanium nitride (TiN), molybdenum nitride, tantalumnitride and zirconium nitride (ZrN), carbides such as titanium carbide (TiC), tungsten carbide (WC), chromium carbide (Cr₂C₂) and doped silicon carbide, and cermet that is a composite material with a metal such as Ni, Co, Fe, Cu, Cr, Ag, and Mo. Particular preference is given to wiring metal materials such as Al, Cr, Cu, Mo and Ti.

It is also acceptable to form the control electrode itself for the switching element using the aforesaid materials, especially a metal material having a high melting point. Since, in this case, it is unnecessary to form any separate light shielding film, the margin for alignment and the space needed for etching can be dispensed with, so that a high-density display system can be set up.

Usually, the thin-film display system of the present invention comprises a thin-film display device such as an EL device, a first switching element for driving the device, a second switching element for driving the first switching element and a selecting circuit (shift register) for selecting a pixel comprising these switching elements, the thin-film display device, etc. Usually, the selecting circuit (shift register) according to the present invention may have any desired construction provided that it is capable of producing a shift output depending on input signals (data). Generally, the shift register is made up of a combination of flip flops. It is here noted that the shift register is used to drive the display screen in a time division mode while the row or column elements thereon are sequentially selected. A circuit equivalent in function to this shift register is also encompassed in the selecting circuit (shift register) of the present invention.

The silicon thin-film layer used herein may be in an amorphous, polycrystal or single crystal form, provided that it can be formed on a substrate and provide a silicon substrate that allows the switching elements formed thereon to perform the necessary functions. Usually, however, polycrystal silicon (p-Si) is preferred. In general, a polycrystal silicon layer may be obtained by annealing an amorphous silicon (a-Si) layer formed by a vapor-phase deposition process. In this case, the obtained polycrystal silicon layer may be either high-temperature p-Si or low-temperature p-Si, although the low-temperature p-Si is preferable.

Especially but not exclusively, the switching element is formed of a semiconductor with the proviso that it allows the control electrode and one set of electrodes to be controlled to be formed on the aforesaid silicon thin-film layer and enables an organic EL device to be directly driven. In order to function the switching element as a display system, however, it is preferable to make use of a TFT (thin-film transistor) type switching element.

More specific constructions and fabrication process steps of the switching elements and thin-film display system used herein are now explained with reference to the accompanying drawings.

First, an a-Si layer 2 is laminated on a substrate 1 by means of sputtering processes, various CVD processes or preferably a plasma CVD process, as depicted in FIG. 4.

Thereafter, the layer 2 is irradiated with an excimer laser 115 or the like for annealing and crystallization, thereby forming an active layer 2a, as depicted in FIG. 5. In this case, thermal annealing may be used in combination.

Furthermore, the crystallized active (polysilicon) layer 2a is patterned byphotolithography to an island form, as depicted in FIG. 6.

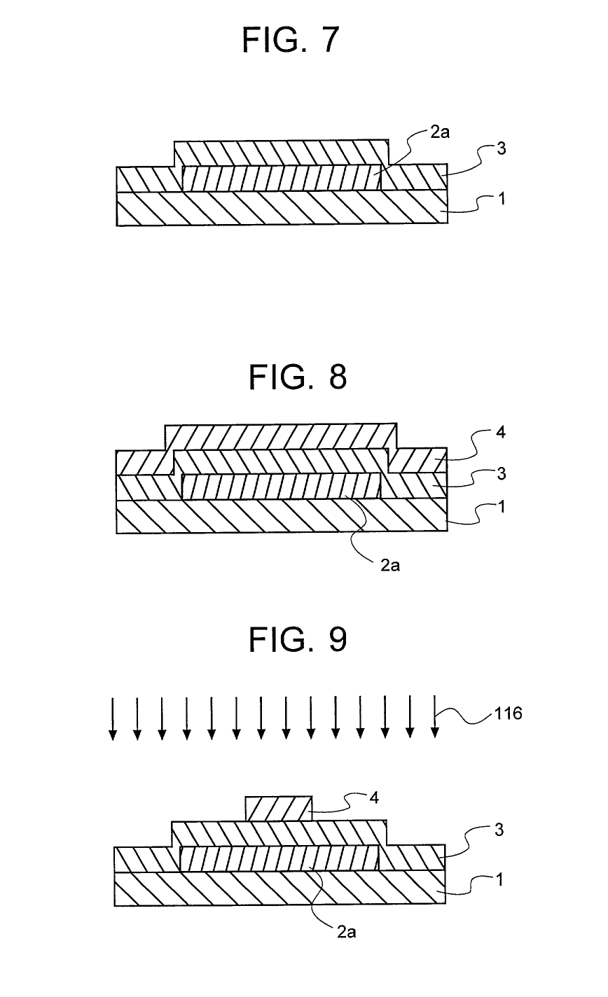

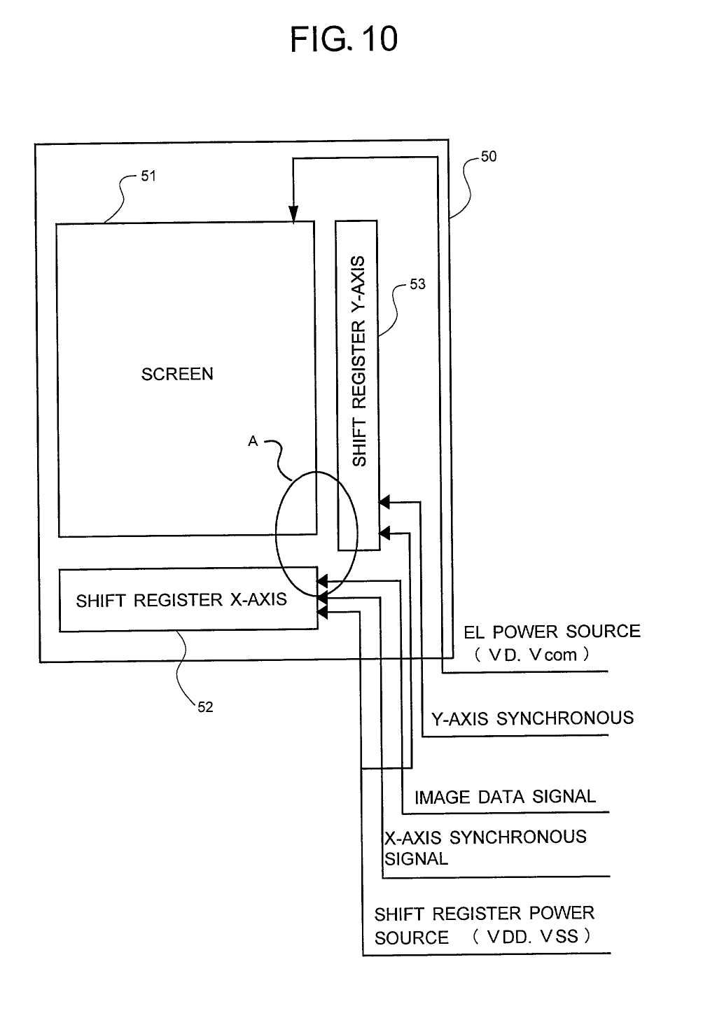

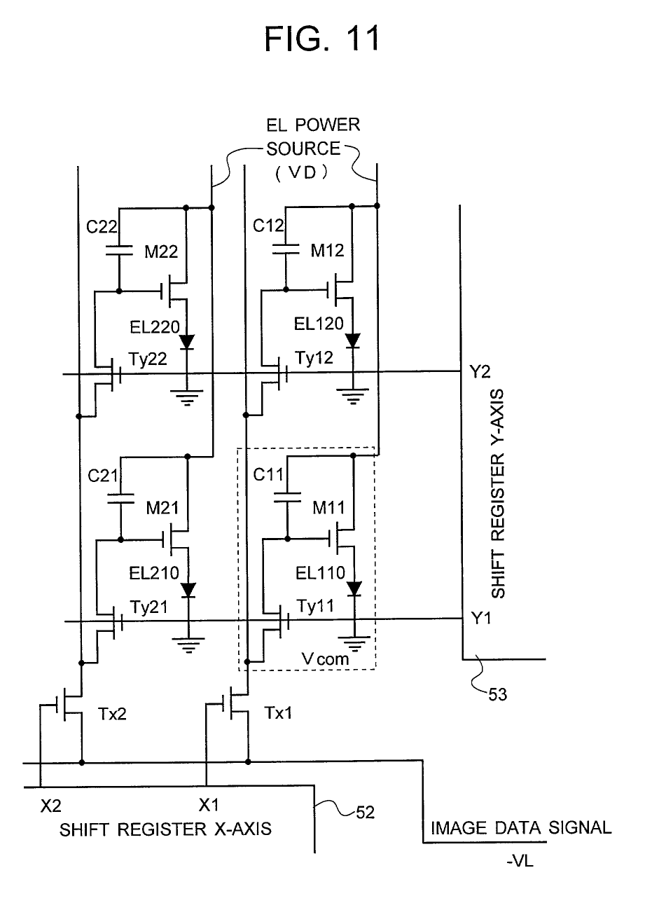

Then, an insulating gate 3 is laminated on the polysilicon island 2a and over the surface of the insulating substrate 1, as depicted in FIG. 7. The substrate temperature is preferably between 250° C. and 400° C. To obtain an insulating gate material of higher quality, annealing should preferably be carried out at 300 to 600° C. for about 1 to about 3 hours.

Then, a film form of gate electrode 4 is provided by evaporation or sputtering, as depicted in FIG. 8.

Then, the gate electrode 4 is patterned, and ion doping 116 is carried out from above the thus patterned gate electrode 4, as depicted in FIG. 9, to form an n+ or p+ site, and signal electrode and scanning electrode lines are thereafter formed by photolithography.

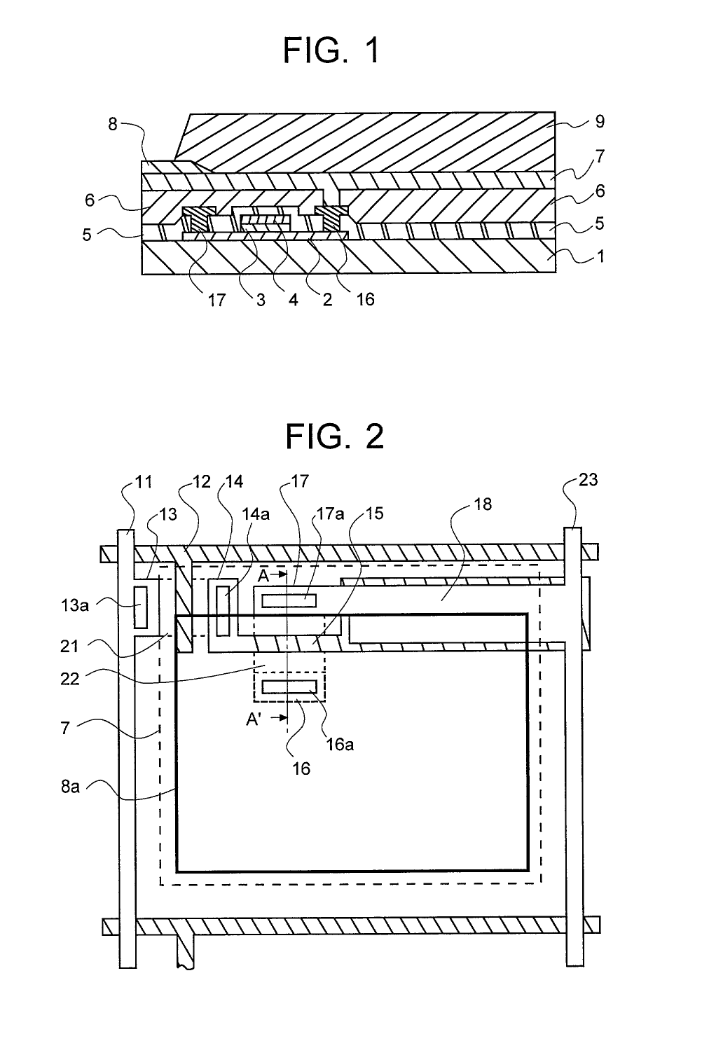

Then, an insulating film 5 is formed as depicted in FIG. 1, and contacts for drain, source, etc. are then formed. The contacts are made under openings in the insulating film 5. First, an SiO₂ film is formed as an interlayer insulating layer by a normal-pressure CVD process. Then, the interlayer insulating layer is etched to form contact holes, thereby making drain and source connecting sites open.

A drain interconnecting electrode 17 and a source interconnecting electrode 16 are formed on the thus opened drain and source sites, respectively, for connection to the drain and source. An additional insulating film 6 is formed on these electrodes. In this case, either one of the drain and source electrodes is allowed to function as the first or second electrode of the organic EL device or, alternatively, connected thereto. In the illustrated embodiment, ITO 7 that is a hole injecting electrode is connected to the source electrode 16 via an opening formed over it. Furthermore, an edge cover 8 for covering a portion other than the pixel portion is formed and an organic EL structure 9 is provided to obtain such a switching element as shown in FIG. 1.

In this case, the ITO is provided in such a way as to provide a covering on the p-Si layer (active layer 2a) 2, especially the switching element, and the edge cover 8 is located in such a way that the organic EL structure 9 is formed on the p-Si layer (active layer 2a) 2. This enables the light extracting area within the pixel to be extended.

In this regard, it is noted that when either one of the interconnecting electrodes is connected to the electrode of the organic EL device, for instance, its hole injecting electrode, it is acceptable to form a connecting metal layer such as a TiN layer for the purpose of improving the connection therebetween.

The thus constructed thin-film display system is now explained more specifically with reference to FIG. 2. FIG. 2 is a plan view illustrative of one embodiment of a TFT array for driving such an organic EL device as shown in FIG. 1. It is here noted that FIG. 1 is a sectional view taken along section A-A′ of FIG. 2.

As shown in FIG. 2, a source bus 11 is connected with a source electrode 13, and then connected to a source site formed on a silicon substrate 21 via a contact hole 13a. The silicon substrate 21 is provided thereon with a gate bus 12 commonly connected to a TFT element of another pixel (not shown). A gate electrode is formed at a site where the gate bus 12 intersects the silicon substrate 21.

A drain site formed on the silicon substrate with a source site and a gate electrode interposed between them is connected with a drain wire 14 via a contact hole 14a. The drain wire 14 is connected to a gate line 15. The gate line 15 is formed on a silicon substrate 22 forming a TFT 2, and connected to one electrode of a capacitor 18. The other electrode of the capacitor 18 is connected to an earth bus 23 and a source electrode 17. The source electrode 17 is connected to a source site of a TFT1 via a contact hole 17a. A gate electrode is formed at a site where the gate line 15 intersects the silicon substrate 22.

A drain site formed on a silicon substrate with a source site and gate electrode 15 interposed between them is connected with a drain wire 16 via a contact hole 16a. The drain wire 16 forms one electrode 7 of the organic EL device defining a pixel or, alternatively, is connected thereto. An opening 8a in an edge cover 8 is located in such a way that the organic EL structure 9 is formed on the p-Si layer (active layer 2a) 2 as well as on the switching device, and an opening is also provided over the p-Si layer (active layer 2a) 2 so as to take emitted light therefrom.

TFT1 for directly driving this organic EL device corresponds to the first switching element, and TFT2 for driving the first switching element corresponds to the second switching element. The source bus 11 and gate bus 12 are connected with selecting circuits although not shown.

The construction of the organic EL device (or the organic EL structure) preferably used as the thin-film light emitting device in the present invention is now explained. The organic EL device comprises between a first electrode and a second electrode an organic layer containing at least an organic material taking part in light emission. Electrons and holes given out of the first and second electrodes are recombined together in the organic layer, thereby emitting light.

Either one of the first and second electrodes serves as a hole injecting electrode and the other as an electron injecting electrode. Usually, however, the first electrode on the substrate side serves as the hole injecting electrode and the second electrodes as the electron injecting electrode.

The electron injecting electrode is preferably formed of a material having a low work function such as K, Li, Na, Mg, La, Ce, Ca, Sr, Ba, Al, Ag, In, Sn, Zn and Zr each in a pure metal element form. To improve the stability of the electron injecting electrode, it is also preferable to use a binary or ternary alloy system containing such metal elements. For the alloy system, for instance, use may be made of Ag·Mg (Ag: 0.1 to 50 at %), Al·Li (Li: 0.01 to 14 at %), In·Mg (Mg: 50 to 80 at %) and Al·Ca (Ca: 0.01 to 20 at %). In this regard, the electron injecting electrode may be formed by an evaporation or sputtering process.

The electron injecting electrode thin film should preferably have at least a certain thickness enough for injection of electrons; it has a thickness of 0.5 nm or greater, preferably 1 nm or greater, and more preferably 3 nm or greater. Although there is no upper limit to the thickness, it is usually preferable that the upper thickness is of the order of 3 to 500 nm. The electron injecting electrode may be provided thereon with an auxiliary or protective electrode.

The evaporation pressure should preferably be between 1.33×10^{-6 Pa} (1×10⁻⁸ Torr) and 1.33×10⁻³ Pa (1×10⁻⁵ Torr), and the heating temperature for an evaporation source should preferably be between about 100° C. and about 1,400° C. for a metal material and between about 10 0° C. and about 500° C. for an organic material.

For the hole injecting electrode, it is preferable to use a transparent or translucent electrode because it is constructed as an electrode out of which emitted light is taken. For the transparent electrode, ITO (tin-doped indium oxide), IZO (zinc-doped indium oxide), ZnO, SnO₂, In₂O₃ or the like may be used. However, ITO (tin-doped indium oxide) and IZO (zinc-doped indium oxide) are preferred. Usually, ITO contains In₂O₃ and SnO₂ in stoichiometric composition; however, the amount of O may deviate slightly therefrom. When transparency is not needed for the hole injecting electrode, the hole injecting electrode may be formed of an opaque material as known in the art.

The hole injecting electrode should preferably have at least a certain thickness enough for injection of holes, and so is of preferably 50 to 500 nm, and more preferably 50 to 300 nm in thickness. Although there is no upper limit to the thickness, it is understood that too large a thickness causes concern about defoliation and too small a thickness offers problems in terms of as-produced film thickness, hole transportation capabilities and resistance value.

The hole injecting electrode layer may be formed by an evaporation process or the like. However, preference is given to sputtering processes and especially a pulse DC sputtering process.

The organic layers in the organic EL structure may be constructed as follows.

The light emitting layer has functions of injecting holes and electrons, transporting them, and recombining holes and electrons to yield excitons. For the light emitting layer, it is preferably to use a relatively electronically neutral compound.

The hole injecting and transporting layer has functions of facilitating injection of holes from the hole injecting electrode, providing stable transportation of holes and blocking electrons. The electron injecting and transporting layer has functions of facilitating injection of electrons from the electron injecting electrode, providing stable transportation of electrons and blocking holes. These layers are effective for increasing the number of holes and electrons injected into the light emitting layer and confining holes and electrons therein for optimizing the recombination region to improve light emission efficiency.

No particular limitation is imposed on the thickness of the light emitting layer, the thickness of the hole injecting and transporting layer, and the thickness of the electron injecting and transporting layer. However, these layers should preferably have a thickness of the order of usually 5 to 500 nm, and especially 10 to 300 nm although varying depending on formation processes.

The thicknesses of the hole injecting and transporting layer, and the electron injecting and transporting layer are approximately equal to, or range from about 1/10 times to about 10 times as large as the thickness of the light emitting layer although they depend on the design of the recombination/light emitting region. When the hole or electron injecting and transporting layer is separated into an injecting layer and a transporting layer, it is preferable that the injecting layer is at least 1 nm thick and the transporting layer is at least 1 nm thick. The upper limit to the thickness is usually about 500 nm for the injecting layer and about 500 nm for the transporting layer. The same film thickness is also true of the case where two injecting and transporting layers are provided.

In the organic EL device according to the present invention, the light emitting layer contains a fluorescent material that is a compound capable of emitting light. The fluorescent material used herein, for instance, may be at least one compound selected from compounds such as those disclosed in JP-A 63-264692, e.g., quinacridone, rubrene, and styryl dyes. Use may also be made of quinoline derivatives such as metal complex dyes containing 8-quinolinol or its derivative as ligands, for instance, tris(8-quinolinolato) aluminum, tetraphenylbutadiene, anthracene, perylene, coronene, and 12-phthaloperinone derivatives. Use may further be made of phenylanthracene derivatives disclosed in JP-A 8-12600 (Japanese Patent Application No. 6-110569) and tetraarylethene derivatives disclosed in JP-A 8-12969 (Japanese Patent Application No. 6-114456).

Preferably, the fluorescent compound is used in combination with a host substance capable of emitting light by itself; that is, it is preferable that the fluorescent compound is used as a dopant. In such a case, the content of the fluorescent compound in the light emitting layer is in the range of preferably 0.01 to 20% by volume, and especially 0.1 to 15% by volume. The content of rubrene in particular is preferably 0.01 to 20% by volume. By using the fluorescent compound in combination with the host substance, it is possible to vary the wavelength performance of light emission of the host substance, thereby making light emission possible on a longer wavelength side and, hence, improving the light emission efficiency and stability of the device.

Quinolinolato complexes, and aluminum complexes containing 8-quinolinol or its derivatives as ligands are preferred for the host substance. Such aluminum complexes are typically disclosed in JP-A's 63-264692, 3-255190, 5-70773, 5-258859, 6-215874, etc.

Exemplary aluminum complexes include tris(8-quinolinolato)aluminum, bis(8-quinolinolato)magnesium, bis(benzo{f}-8-quinolinolato)zinc, bis(2-methyl-8-quinolinolato)aluminum oxide, tris(8-quinolinolato)indium, tris(5-methyl-8-quinolinolato)aluminum, 8-quinolinolatolithium, tris(5-chloro-8-quinolinolato)gallium, bis(5-chloro-8-quinolinolato)calcium, 5,7-dichloro-8-quinolinolato-aluminum, tris(5,7-dibromo-8hydroxyquinolinolato)aluminum, and poly[zinc(II)-bis(8hydroxy-5-quinolinyl)methane].

Other preferable host substances include phenyl-anthracene derivatives disclosed in JP-A 8-12600, tetraarylethene derivatives set forth in JP-A 8-12969, etc.

The light emitting layer may also serve as an electron injecting and transporting layer. In such a case, it is preferable to use tris(8-quinolinolato)aluminum or the like. These fluorescent materials may be provided by evaporation.

If necessary or preferably, the light emitting layer is formed of a mixed layer of at least one compound capable of injecting and transporting holes with at least one compound capable of injecting and transporting electrons. Preferably in this case, a dopant is incorporated in the mixed layer. The content of the dopant compound in the mixed layer is in the range of preferably 0.01 to 20% by volume, and especially 0.1 to 15% by volume.

In the mixed layer with a hopping conduction path available for carriers, each carrier migrates in the polarly prevailing substance, so making the injection of carriers having an opposite polarity unlikely to occur. This leads to an increase in the service life of the device due to less damage to the organic compound. By incorporating the aforesaid dopant in such a mixed layer, it is possible to vary the wavelength performance of light emission that the mixed layer itself possesses, thereby shifting the wavelength of light emission to a longer wavelength side and improving the intensity of light emission, and the stability of the device as well.

The compound capable of injecting and transporting holes and the compound capable of injecting and transporting electrons, both used to form the mixed layer, may be selected from compounds for the injection and transportation of holes and compounds for the injection and transportation of electrons, as will be described later. Especially for the compounds for the injection and transportation of holes, it is preferable to use amine derivatives having strong fluorescence, for instance, hole transporting materials such as triphenyldiamine derivatives, styrylamine derivatives, and amine derivatives having an aromatic fused ring.

For the compounds capable of injecting and transporting electrons, it is preferable to use metal complexes containing quinoline derivatives, especially 8-quinolinol or its derivatives as ligands, in particular, tris(8-quinolinolato) aluminum (Alq3). It is also preferable to use the aforesaid phenylanthracene derivatives, and tetraarylethene derivatives.

For the compounds for the injection and transportation of holes, it is preferable to use amine derivatives having strong fluorescence, for instance, hole transporting materials such as triphenyldiamine derivatives, styrylamine derivatives, and amine derivatives having an aromatic fused ring.

In this case, the ratio of mixing the compound capable of injecting and transporting holes with respect to the compound capable of injecting and transporting electrons is determined while the carrier mobility and carrier density are taken into consideration. In general, however, it is preferred that the weight ratio between the compound capable of injecting and transporting holes and the compound capable of injecting and transporting electrons is of the order of 1/99 to 99/1, particularly 10/90 to 90/10, and more particularly 20/80 to 80/20.

The thickness of the mixed layer should preferably be equal to or larger than the thickness of a single molecular layer, and less than the thickness of the organic compound layer. More specifically, the mixed layer has a thickness of preferably 1 to 85 nm, more preferably 5 to 60 nm, and even more preferably 5 to 50 nm.

Preferably, the mixed layer is formed by co-evaporation where the selected compounds are evaporated from different evaporation sources. When the compounds to be mixed have identical or slightly different vapor pressures (evaporation temperatures), however, they may have previously been mixed together in the same evaporation board for the subsequent evaporation. Preferably, the compounds are uniformly mixed together in the mixed layer. However, the compounds in an island form may be present in the mixed layer. The light emitting layer may generally be formed at a given thickness by the evaporation of the organic fluorescent substance or coating a dispersion of the organic fluorescent substance in a resin binder.

For the hole injecting and transporting layer, use may be made of various organic compounds as disclosed in JP-A's 63-295695, 2-191694, 3-792,5-234681, 5-239455, 5-299174, 7-126225, 7-126226 and 8-100172 and EP 0650955A1. Examples are tetraarylbenzidine compounds (triaryldiamine or triphenyl-diamine (TPD)), aromatic tertiary amines, hydrazone derivatives, carbazole derivatives, triazole derivatives, imidazole derivatives, oxadiazole derivatives having an amino group, and polythiophenes. The compounds may be used singly or in combination of two or more. Where two or more such compounds are used, they may be stacked as separate layers, or otherwise mixed.

When the hole injecting and transporting layer is provided as a separate hole injecting layer and a separate hole transporting layer, a preferable combination of two or more compounds may be selected from the compounds for the hole injecting and transporting layer. In this regard, it is preferable to laminate the compounds on the hole injecting electrode side (ITO or the like) in increasing ionization potential order. It is also preferable to use a compound having good thin-film formation capability at the surface of the hole injecting electrode. This order of lamination holds for the provision of two or more hole injecting and transporting layers, and is effective as well for lowering driving voltage and preventing the occurrence of current leakage and the appearance and growth of dark spots. Since deposition by evaporation is utilized for device fabrication, films as thin as about 1 to 10 nm can be formed in a uniform and pinhole-free state, which restrains any change in color tone of emitted light and a drop of efficiency by re-absorption even if a compound having a low ionization potential and absorption in the visible range is used in the hole injecting layer. The hole injecting and transporting layer may be formed by the evaporation of the aforesaid compound as is the case with the light emitting layer.

For the electron injecting and transporting layer used when the organic electron injecting and transporting layer is provided, there may be used quinoline derivatives such as organic metal complexes containing 8-quinolinol or its derivatives as ligands, for instance, tris(8-quinolinolato)aluminum (Alq3), oxadiazole derivatives, perylene derivatives, pyridine derivatives, pyrimidine derivatives, quinoxaline derivative, diphenylquinone derivatives, and nitro-substituted fluorene derivatives. The electron injecting and transporting layer may also serve as a light emitting layer. In this case, it is preferable to use tris(8-quinolilato)aluminum, etc. The electron injecting and transporting layer may be formed as by evaporation, as is the case with the light emitting layer.

When the electron injecting and transporting layer is provided as a separate electron injecting layer and a separate electron transporting layer, a preferable combination of two or more compounds may be selected from the compounds for the electron injecting and transporting layer. In this regard, it is preferable to laminate the compounds on the electron injecting electrode side in decreasing electron affinity order. This order of lamination holds for the provision of two or more electron injecting and transporting layers.

Preferably, the hole injecting and transporting layer, the light emitting layer, and the electron injecting and transporting layer are formed by a vacuum evaporation process because a uniform thin film can then be obtained. With the vacuum evaporation process, it is thus possible to obtain a uniform thin film in an amorphous state or with a grain size of up to 0.2 μm. A grain size of greater than 0.2 μm results in non-uniform light emission. To avoid this, it is required to make the driving voltage of the device high. However, this in turn gives rise to some considerable drop of charge injection efficiency.

No particular limitation is imposed on the conditions for vacuum evaporation. However, the vacuum evaporation should preferably be carried out at a degree of vacuum of up to 10⁻⁴ Pa and a film deposition rate of about 0.01 to 1 nm/sec. Also, the layers should preferably be continuously formed in vacuum, partly because the deposition of impurities on the interface between adjacent layers is avoidable resulting in the achievement of high performance, and partly because the driving voltage of the device can be lowered with elimination of dark spots or no growth of dark spots.

When the layers, each containing a plurality of compounds, are formed by the vacuum evaporation process, it is preferable that co-evaporation is carried out while each board with the compounds charged therein is placed under temperature control.

The substrate may be provided with a color filter film or a color conversion film containing a fluorescent material or a dielectric reflecting film for control of emitted colors.

For the color filter film, use may be made of a color filter commonly used with liquid crystal displays, etc. Preferably in this case, however, the properties of the color filter used should be controlled in conformity with the colors of light emitted from the organic EL device to optimize light extraction efficiency and color purity.

If use is made of a color filter capable of cutting off extraneous light of such short wavelengths as absorbed by the EL device material or fluorescence conversion layer, it is then possible to improve the light resistance of the device and the contrast of what is displayed thereon.

Alternatively, an optical thin film such as a dielectric multilayer film may be used in place of the color filter.

The fluorescent color conversion film absorbs light emitted from the EL device and gives out light from the fluorescent material contained therein for the color conversion of light emission, and is composed of three components, a binder, a fluorescent material and a light absorbing material.

For the fluorescent material, it is basically preferable to use a fluorescent material having high fluorescent quantum efficiency, and especially a fluorescent material having strong absorption in an EL light emission wavelength region. Laser dyes are suitable for the practice of the invention. To this end, for instance, it is preferable to use laser dyes, for instance, rohodamine compounds, perylene compounds, cyanine compounds, phthalocyanine compounds (including subphthalocyanine compounds, etc.), naphthaloimide compounds, fused cyclic hydrocarbon compounds, fused heterocyclic compounds, styryl compounds, and coumarin compounds.

For the binder, it is basically preferable to make an appropriate selection from materials that do not extinguish fluorescence. It is particularly preferable to use a material that can be finely patterned by photolithography, printing or the like. It is also preferable to use a material that is not damaged during hole injecting electrode (ITO or IZO) film formation.

The light absorbing material is used when light is not fully absorbed by the fluorescent material, and so may be dispensed with, if not required. For the light absorbing material, it is preferable to make a selection from materials that do not extinguish fluorescence.

The organic EL device according to the present invention is generally of the DC drive type or pulse drive type. The applied voltage is usually of the order of 2 to 30 volts.

### EXAMPLE

### Example 1

An active matrix circuit was constructed through such steps as shown in FIGS. 4 to 9 to fabricate a thin-film display system of such construction as shown in FIGS. 1 and 2.

An amorphous silicon layer 2 was formed on a substrate of Corning 1737 heat-resistant non-alkali glass at a thickness of about 60 nm (600 Å) by a low-pressure CVD (LPCVD) process under the following conditions:

Si₂H₆ Gas: 100 SCCM,

Pressure: 40 Pa (0.3 Torr), and

Temperature: 480° C.

Then, the amorphous silicon layer 2 was converted by solid-phase growth into an active layer (polysilicon layer) 2a. For this solid-phase growth, thermal annealing was used in combination with laser annealing 115 under the following conditions.

### Thermal Annealing

N₂: 1 SLM p1 Temperature: 600° C.

Annealing Time: 24 hours

### Laser Annealing

KrF: 254 nm

Energy Density: 200 mJ/cm²

Number of Shots: 200

Then, the polysilicon layer was patterned to obtain an active silicon layer 2a of 50 nm (500 Å) in thickness.

An SiO₂ layer forming a gate oxide film 3 was formed on the active silicon layer 2a at a thickness of about 80 nm (800 Å) as by a plasma CVD process under the following film formation conditions:

Input Power: 50 W,

TEOS (tetraethoxysilane) Gas: 50 SCCM,

O₂: 500 SCCM,

Pressure: 13.3 to 66.5 Pa (0.1 to 0.5 Torr), and

Temperature: 350° C.

An Mo-Si₂ layer forming a gate electrode 4 was formed on the SiO₂ layer at a thickness of about 100 nm (1,000 Å) by means of a sputtering process. Then, the Mo-Si₂ layer and the aforesaid SiO₂ layer were patterned as by dry etching, thereby obtaining the gate electrode 4 and gate oxide film 3. It was noted that the transmittance of the obtained gate electrode with respect to light in the emitted light wavelength range is reduced down to almost zero, and so the electrode can also function as a light shielding film.

Then, using a doping mask and the aforesaid gate electrode 4 as a mask, P type impurities 116:B were doped by an ion doping process on a site to provide a source-drain region of the silicon active layer, followed by doping of the channel site with a small amount of the impurities, thereby forming the first switching element, second switching element and switching element for a selecting circuit. It is here noted that the doping conditions for the source and drain sites may be similar to those for general TFT fabrication processes.

Then, the structure was heated at about 550° C. for 10 hours in a nitrogen atmosphere to activate the dopant. In addition, the structure was heated at about 400° C. for 30 minutes in a hydrogen atmosphere for hydrogenation, thereby decreasing the defect level density of the semiconductor.

Then, an SiO₂ layer forming an interlayer insulating layer was formed all over the substrate at a thickness of about 800 nm (8,000 Å). The SiO₂ film forming an interlayer insulating layer 6 was formed under the following film formation conditions:

O₂/N₂: 10 SLM,

5% SiH₄/N₂: 1 SLM,

1% PH₃/N₂: 500 SCCM,

N₂: 10 SLM,

Temperature: 410° C., and

Pressure: atmospheric pressure.

The SiO₂ film to form the interlayer insulating layer 6 was etched to form a contact hole. Then, Al was deposited by evaporation to form drain and source interconnecting electrodes 16 and 17.

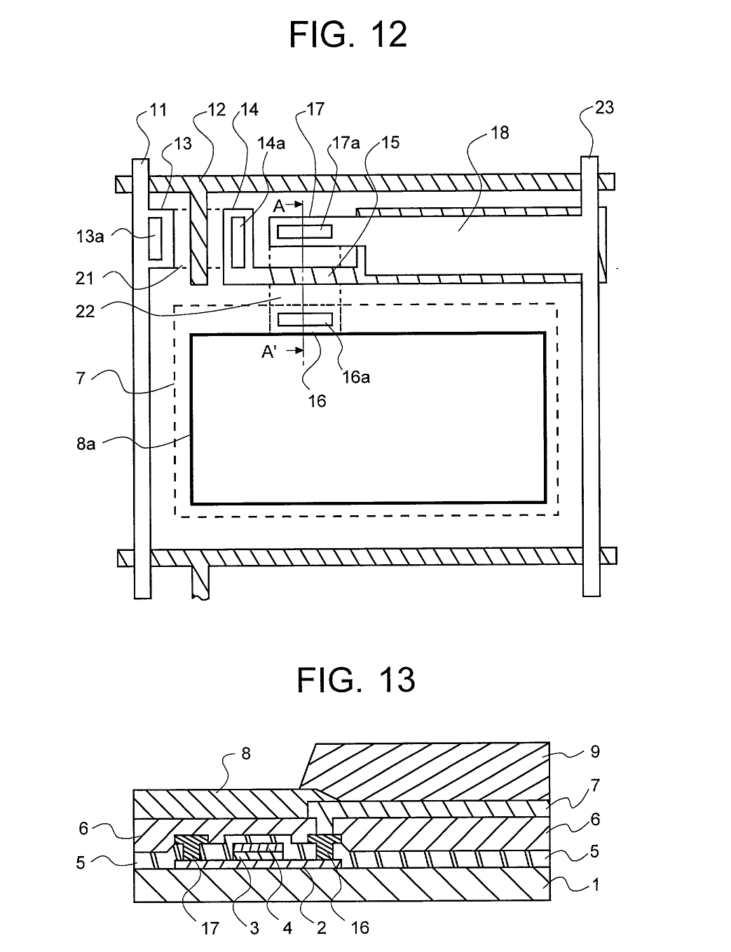

Then, an ITO 7 film to provide a hole injecting electrode was formed on the region on which the organic EL device was to be formed, and connected to the aforesaid interconnecting electrode 16. To allow a light emitting region (a pixel portion) alone to emit light, an interlayer insulating film SiO₂ (edge cover) 8 was formed at a thickness of 400 nm (4,000 Å), and provided with an opening to provide a light emitting region. In this case, the ITO film was formed in such a way as to provide a covering on the p-Si layer (active layer 2a) 2, especially on the switching element, and the edge cover 8 was formed in such a way that the organic EL structure 9 was also formed on the p-Si layer (active layer 2a) 2. As a result, the emitted light extracting area in the pixel could be increased. For the purpose of comparison, a comparative sample with no organic EL structure 9 formed on a silicon thin film such as a TFT was also prepared as shown in FIGS. 12 and 13.

The organic layers of the organic EL structure 9 including a light emitting layer were formed at the pixel region (opening 8a) of the thus obtained inventive sample, and comparative sample TFT thin-film pattern by means of a vacuum evaporation process. The film-forming materials used herein are set out below. The materials are referred to as an example alone. However, it is noted that the present invention, as can be understood from its concept, may be applied to any desired film-forming material provided that it can be formed by an evaporation process.

Subsequently, N,N -bis(m-methyl phenyl)-N,N′-diphenyl-1,1′-biphenyl-4,4′-diamine (TPD for short) was provided in the form of a hole injecting layer and a hole transporting layer, and tris(8-hydroxyquinoline)aluminum (Alq3 for short) was provided in the form of a combined light emitting layer and electron transporting layer. In addition, a cathode was formed as the second electrode while the vacuum was still kept.

To form these films, a vacuum evaporation process was selected for the hole injecting layer and hole transporting layer and a DC sputtering process was selected for the second electrode. For the second electrode, an Al/Li alloy (having an Li concentration of 7 at %) was formed to a thickness of just 5 nm at a gas pressure of 1 Pa and a power of 1 W/cm², and an additional Al for an interconnecting electrode was laminated thereon to a thickness of 200 nm at 0.3 Pa and a power of 1 W/cm².

Each pixel of the thus obtained organic EL display system was driven at a constant current of 10 mA/cm². As a result, it was found that the on-off operation (light emission) can occur according to the TFT operation without any trouble. It was also found that the area of the light extraction region (opening 8a) in the pixel is at least 15% larger than that in a conventional sample. The inventive and comparative samples were driven at the current needed to obtain the same luminance, thereby finding the half-life of luminance. As a result, it was found that the half-life of the inventive sample is at least 1.2 times as long as that of the comparative sample.

### Example 2

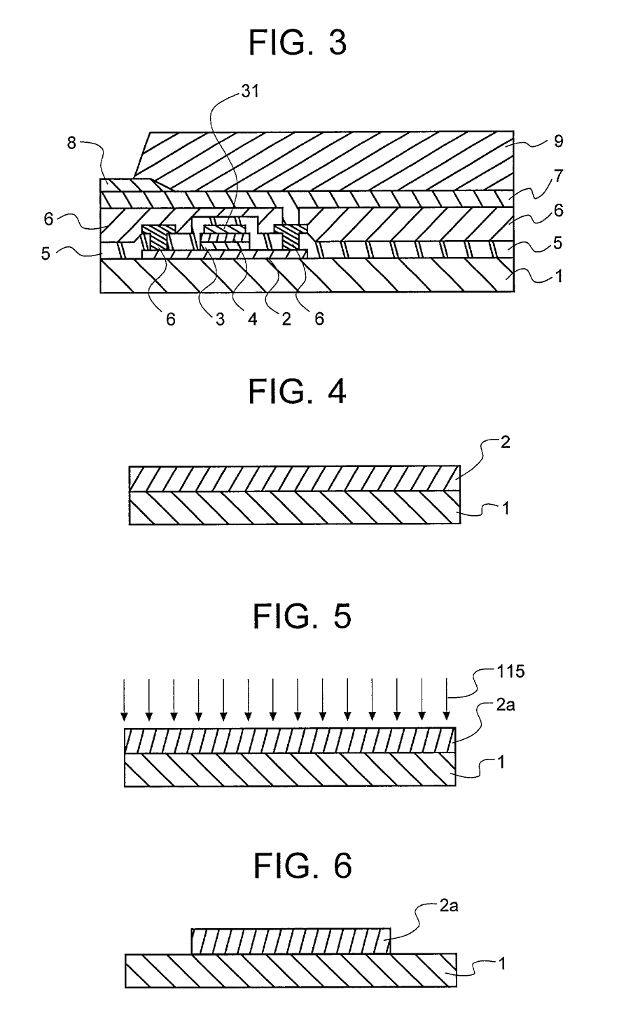

In Example 1, the gate electrode 4 was formed of p-Si and a light shielding film 31 was formed thereon, as depicted in FIG. 3. Having a film thickness of 200 nm, the light shielding film 31 was substantially equal in size to the gate electrode and formed of titanium nitride (TiN) that was an interconnecting electrode material. Thus, the light shielding film could be formed at the step of forming the interconnecting electrode, resulting in no substantial increase in the number of steps. Otherwise, a thin-film display system was prepared as in Example 1.

The obtained sample was driven and evaluated as in Example 1. As a result, much the same results as in Example 1 were obtained.

### EFFECT OF THE INVENTION

According to the present invention as explained above, it is possible to provide an active matrix type of thin-film display system that is allowed to have high luminance and high reliability by increasing the proportion of the thin-film display device in a pixel.

Japanese Patent Application No. 18659/2000 is incorporated herein by reference.

Although some preferable embodiments have been described, many modifications and variations may be made thereto in the light of the above teachings. It is therefore to be understood that within the scope of the appended claims, the invention may be practiced otherwise than as specifically described.

What we claim is:

1. A thin-film display system comprising, on the same substrate, a thin-film display device driven at a current for each pixel to emit light and a silicon thin-film layer on which a circuit for driving the thin-film display device is formed, which further comprises a region where at least said thin-film display device and said silicon thin-film layer overlap each other in a film thickness direction, wherein a part of light emitted from said thin-film display device is taken out of said region.

2. The thin-film display system according to claim 1, wherein said silicon thin-film layer is provided with a switching element for driving said thin-film light emitting device.

3. The thin-film display system according to claim 1 or 2, wherein a part of light emitted from said thin-film display device is taken out of a region with said switching element formed thereon.

4. The thin-film display system according to claim 1, wherein at least a part of a channel region in said switching element is shielded from light by a material having no light transmission properties.

5. The thin-film display system according to claim 1, wherein a control electrode for said switching element is formed of a material opaque to light.

6. The thin-film display system according to claim 1, wherein said switching element is formed of a polysilicon thin film.

7. The thin-film display system according to claim 1, wherein said switching element is a thin-film transistor.

8. The thin-film display system according to claim 1, wherein said thin-film display device is an organic EL device.
